(19) United States
(12) Patent Application Publication
(10) Pub. No.: US 2025/0031457 A1
(43) Pub. Date: Jan. 23, 2025

(54) SELF-PROTECTED ELECTROSTATIC DISCHARGE PROTECTION DEVICES

(71) Applicant: GlobalFoundries U.S. Inc., Malta, NY (US)

(72) Inventors: Sagar Premnath Karalkar, Essex Junction, VT (US); . Ajay, Aligarh (IN); Souvick Mitra, Essex Junction, VT (US); Kyong Jin Hwang, Singapore (SG)

(21) Appl. No.: 18/223,780

(22) Filed: Jul. 19, 2023

(51) Int. Cl. H01L 27/02

(52) U.S. Cl. CPC H01L 27/0262

(57) ABSTRACT

Structures for an electrostatic discharge protection device and methods of forming same. The structure comprises a semiconductor substrate including a well, a field-effect transistor including a gate, a source having a doped region in the well, and a drain, and a silicon-controlled rectifier including a doped region in the well.

### BACKGROUND

The disclosure relates generally to semiconductor devices and integrated circuit fabrication and, more specifically, to structures for an electrostatic discharge protection device and methods of forming same.

An integrated circuit may be exposed to random electrostatic discharge (ESD) events that can direct large and damaging ESD currents to the sensitive devices of the integrated circuit. An ESD event refers to an unpredictable electrical discharge over a short duration and during which a large positive or negative current is directed toward the integrated circuit. ESD events may occur during post-manufacture chip handling or after chip installation on a circuit board or other carrier. ESD events may originate from a variety of sources, such as the human body, a machine component, or a chip carrier.

Precautions may be taken to protect an integrated circuit from an ESD event. One such precaution consists of an on-chip protection circuit that is designed to avert damage to the sensitive devices of the integrated circuit during an ESD event. If an ESD event occurs, the protection circuit triggers a protection device to enter a low-impedance state that conducts the ESD current to ground and thereby shunts the ESD current away from the sensitive devices of the integrated circuit. The protection device remains clamped in its low-impedance state until the ESD current is drained and the ESD voltage is discharged to an acceptable level.

A laterally-diffused metal-oxide-semiconductor (LDMOS) device, also known as an extended-drain metal-oxide-semiconductor (EDMOS) device, is a type of field-effect transistor designed to handle high voltages by incorporating additional transistor features, such as a lightly-doped drift well providing an extended drain region. A laterally-diffused metal-oxide-semiconductor device, which may be used as a protection device in an on-chip protection circuit, is itself susceptible to damage from an ESD event.

Improved structures for an electrostatic discharge protection device and methods of forming same are needed.

### SUMMARY

In an embodiment, a structure for an electrostatic discharge protection device is provided. The structure comprises a semiconductor substrate including a well, a field-effect transistor including a gate, a source having a doped region in the well, and a drain, and a silicon-controlled rectifier including a doped region in the well.

In an embodiment, a method of forming a structure for an electrostatic discharge protection device is provided. The method comprises forming a well in a semiconductor substrate, forming a field-effect transistor that includes a gate, a source having a doped region in the well, and a drain, and forming a silicon-controlled rectifier that includes a doped region in the well.

### BRIEF DESCRIPTION OF THE DRAWINGS

The accompanying drawings, which are incorporated in and constitute a part of this specification, illustrate various embodiments of the invention and, together with a general description of the invention given above and the detailed description of the embodiments given below, serve to explain the embodiments of the invention. In the drawings, like reference numerals are used to indicate like features in the various views.

FIG. 1 is a cross-sectional view of a structure in accordance with embodiments of the invention.

FIG. 2 is a cross-sectional view of the structure at a fabrication stage subsequent to FIG. 1.

FIG. 3 is a cross-sectional view of a structure in accordance with alternative embodiments of the invention.

FIG. 4 is a cross-sectional view of a structure in accordance with alternative embodiments of the invention.

FIG. 5 is a cross-sectional view of a structure in accordance with alternative embodiments of the invention.

FIG. 6 is a top view of a layout for a structure in accordance with embodiments of the invention.

### DETAILED DESCRIPTION

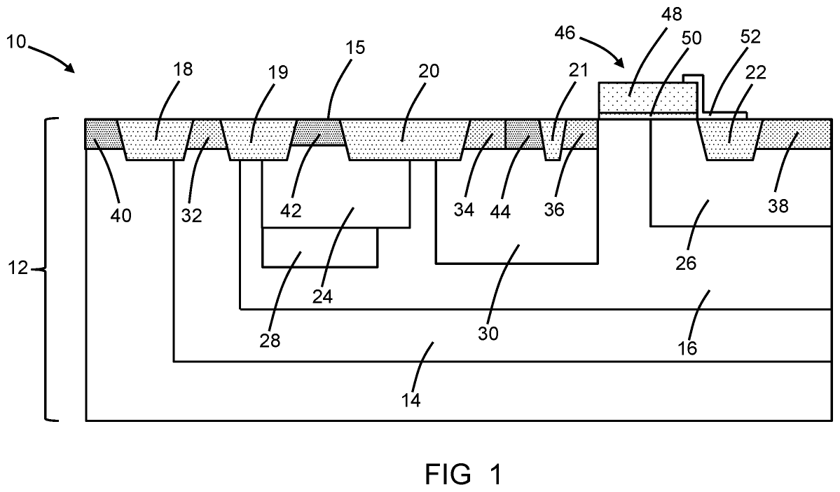

With reference to FIG. 1 and in accordance with embodiments of the invention, a device structure 10 includes a semiconductor substrate 12, a high-voltage well 14 and a high-voltage well 16 in the semiconductor substrate 12, and shallow trench isolation regions 18, 19, 20, 21, 22 in the semiconductor substrate 12. The semiconductor substrate 12 may be comprised of a semiconductor material, such as single-crystal silicon and may be lightly doped to have p-type conductivity. The high-voltage well 14 and the high-voltage well 16 may be deep wells that are doped to have opposite conductivity types. The shallow trench isolation regions 18, 19, 20, 21, 22 may be formed by patterning shallow trenches in the semiconductor substrate 12 with lithography and etching processes, depositing a dielectric material, such as silicon dioxide, in the shallow trenches, and recessing and/or planarizing the deposited dielectric material.

In an embodiment, the high-voltage well 14 may be lightly doped with a concentration of a n-type dopant (e.g., arsenic or phosphorus) such that the high-voltage well 14 has n-type conductivity. In an embodiment, the high-voltage well 14 may be formed by introducing a dopant by, for example, a masked ion implantation into the semiconductor substrate 12. A patterned implantation mask may be formed to define a selected area (e.g., location and horizontal dimensions) on a top surface 15 of the semiconductor substrate 12 that is exposed for implantation to form the high-voltage well 14. The implantation conditions (e.g., ion species, dose, kinetic energy) may be selected to tune the electrical and physical characteristics of the high-voltage well 14.

In an embodiment, the high-voltage well 16 may be lightly doped with a concentration of a p-type dopant (e.g., boron) such that the high-voltage well 16 has p-type conductivity. In an embodiment, the high-voltage well 16 may be formed by introducing a dopant by, for example, a masked ion implantation into the semiconductor substrate 12. A patterned implantation mask may be formed to define a selected area (e.g., location and horizontal dimensions) on the top surface 15 of the semiconductor substrate 12 that is exposed for implantation to form the high-voltage well 16. The implanted area for the high-voltage well 16 may be smaller than the implanted area for the high-voltage well 14 and overlap with the implanted area of the high-voltage well 14 such that the high-voltage well 16 is surrounded by, or embedded in, the high-voltage well 14. The implantation conditions (e.g., ion species, dose, kinetic energy) may be selected to tune the electrical and physical characteristics of the high-voltage well 16.

Wells 24, 26 may be formed in respective portions of the semiconductor substrate 12, and a well 28 may also be formed in a portion of the semiconductor substrate 12. In an embodiment, the wells 24, 26 and the well 28 may contain a concentration of an n-type dopant (e.g., arsenic or phosphorus) to provide n-type conductivity. The well 28 adjoins the well 24, and the well 28 is disposed at a greater depth in the semiconductor substrate 12 than the well 24. The wells 24, 26 may have a higher dopant concentration than the well 28. The wells 24, 26 and the well 28 have an opposite conductivity type from the high-voltage well 16.

In an embodiment, the wells 24, 26 may be formed by introducing a dopant by, for example, a masked ion implantation into the semiconductor substrate 12. A patterned implantation mask may be formed to define selected areas (e.g., locations and horizontal dimensions) on the top surface 15 of the semiconductor substrate 12 that is exposed for implantation to form the wells 24, 26. The implantation conditions (e.g., ion species, dose, kinetic energy) may be selected to tune the electrical and physical characteristics of the wells 24, 26. In an embodiment, the well 28 may be formed by introducing a dopant by, for example, a masked ion implantation into the semiconductor substrate 12. A patterned implantation mask may be formed to define a selected area (e.g., location and horizontal dimensions) on the top surface 15 of the semiconductor substrate 12 that is exposed for implantation to form the well 28.

A well 30 may be formed in a portion of the semiconductor substrate 12. The well 30 may have an opposite conductivity type from the wells 24, 26 and an opposite conductivity type from the well 28. The well 30 may have the same conductivity type as the high-voltage well 16 but at a higher dopant concentration. In an embodiment, the well 30 may contain a concentration of a p-type dopant (e.g., boron) to provide p-type conductivity. In an embodiment, the well 30 may be formed by introducing a dopant by, for example, a masked ion implantation into the semiconductor substrate 12. A patterned implantation mask may be formed to define a selected area (e.g., location and horizontal dimensions) on the top surface 15 of the semiconductor substrate 12 that is exposed for implantation to form the well 30.

The well 30 is disposed in a lateral direction between the well 24 and the well 26. A portion of the high-voltage well 16 is disposed between the well 24 and the well 30, and a portion of the high-voltage well 16 is disposed between the well 26 and the well 30. The shallow trench isolation region 20 includes a portion that overlaps with the well 24, and the shallow trench isolation region 20 includes another portion that overlaps with the well 30. The overlap between the well 24 and the shallow trench isolation region 20, as well as the overlap between the well 28 and the shallow trench isolation region 20, may represent variables that can be used to tune the performance of the device structure 10. The overlap between the well 30 and the shallow trench isolation region 20 may represent a variable that can be used to tune the performance of the device structure 10.

Doped regions 32, 34, 36, 38 are formed in respective portions of the semiconductor substrate 12. The doped region 32, which is disposed in the high-voltage well 14, adjoins the top surface 15 of the semiconductor substrate 12 between the shallow trench isolation region 18 and the shallow trench isolation region 19. The doped region 32 provides a contact to the high-voltage well 14. The doped region 34, which is disposed in the well 30, adjoins the top surface 15 of the semiconductor substrate 12 adjacent to the shallow trench isolation region 20. The doped region 36, which is disposed in the well 30, adjoins the top surface 15 of the semiconductor substrate 12 adjacent to the shallow trench isolation region 21. The doped region 38, which is disposed in the well 26, adjoins the top surface 15 of the semiconductor substrate 12 adjacent to the shallow trench isolation region 22.

The doped region 32 may be doped to the same conductivity type as the high-voltage well 14 but at a higher dopant concentration, the doped regions 34, 36 may be doped to have an opposite conductivity type from the well 30, and the doped region 38 may be doped to the same conductivity type as the well 26 but at a higher dopant concentration. In an embodiment, the doped regions 32, 34, 36, 38 may contain a concentration of an n-type dopant (e.g., arsenic or phosphorus) to provide n-type conductivity. The doped regions 32, 34, 36, 38 may be concurrently formed by selectively implanting ions, such as ions including the n-type dopant, with an implantation mask having openings defining the intended locations for the doped regions 32, 34, 36, 38 in the semiconductor substrate 12. The implantation conditions (e.g., ion species, dose, kinetic energy) may be selected to tune the electrical and physical characteristics of the doped regions 32, 34, 36, 38.

A doped region 40 is disposed in a portion of the semiconductor substrate 12 adjacent to the shallow trench isolation region 18. A doped region 42 is disposed in a portion of the well 24, and a doped region 44 is disposed in a portion of the well 30. The doped regions 40, 42, 44 adjoin the top surface 15 of the semiconductor substrate 12. The doped region 40 provides a contact to the semiconductor substrate 12. In that regard, the doped region 40 may be doped to have the same conductivity type as the semiconductor substrate 12 but at a higher dopant concentration. The doped region 42 may be doped to have an opposite conductivity type from the well 24 as the semiconductor substrate 12. The doped region 44 may be doped to have the same conductivity type as the well 30 but at a higher dopant concentration. In an embodiment, the doped regions 40, 42, 44 may contain a concentration of a p-type dopant (e.g., boron) to provide p-type conductivity. The doped regions 40, 42, 44 may be concurrently formed by selectively implanting ions, such as ions including the p-type dopant, with an implantation mask having openings defining the intended locations for the doped regions 40, 42, 44 in the semiconductor substrate 12. The implantation conditions (e.g., ion species, dose, kinetic energy) may be selected to tune the electrical and physical characteristics of the doped regions 40, 42, 44.

A gate 46 is formed on, and over, a portion of the top surface 15 of the semiconductor substrate 12. The gate 46 includes a gate conductor layer 48 and a gate dielectric layer 50 that are formed in a layer stack with the gate dielectric layer 50 positioned between the gate conductor layer 48 and the top surface 15. In an embodiment, the gate conductor layer 48 may be comprised of a conductor, such as doped polysilicon, and the gate dielectric layer 50 may be comprised of a dielectric material, such as silicon dioxide. The gate 46 overlaps with an underlying portion of the well 26, and the gate 46 also overlaps with an underlying portion of the high-voltage well 16 between the well 26 and the well 30. The overlapped portion of the well 26 and the overlapped portion of the high-voltage well 16 are characterized by opposite conductivity types. The shallow trench isolation region 22 is laterally disposed in the semiconductor substrate 12 between the gate 46 and the doped region 38. The shallow trench isolation region 22, which adjoins the gate dielectric layer 50, is thicker than the gate dielectric layer 50.

A dielectric layer 52 comprised of a dielectric material, such as silicon nitride, may be deposited and then patterned by lithography and etching processes. The dielectric layer 52 may fully overlap with a side of the gate 46. The dielectric layer 52 may function as a silicide-blocking layer.

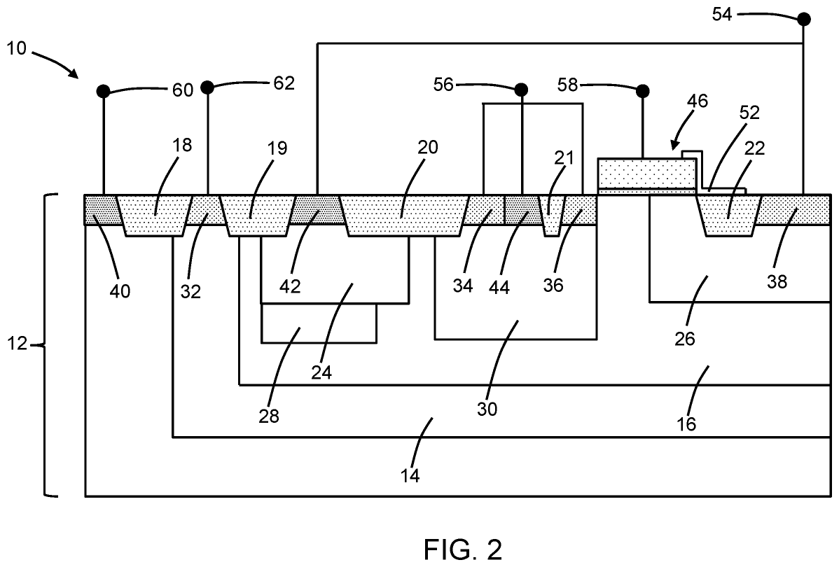

With reference to FIG. 2 in which like reference numerals refer to like features in FIG. 1 and at a subsequent fabrication stage, the device structure 10 may be configured by electrical connections as an electrostatic discharge protection device that is self-protected against an electrostatic discharge event. The device structure 10 includes a field-effect transistor in the form of a laterally-diffused metal-oxide-semiconductor device (i.e., an extended-drain metal-oxide-semiconductor device) that has a drain defined by the well 26 and doped region 38, as well as a source defined by the doped region 36. The well 26 defines a drift region that is doped at a lower dopant concentration than the doped region 38. The gate 46 is disposed in a lateral direction between the source and drain.

The doped region 38 of the drain of the laterally-diffused metal-oxide-semiconductor device is physically and electrically connected by an electrical connection in an interconnect structure to an input/output pad 54 that is under protection against an electrostatic discharge event. The doped region 36 of the source of the laterally-diffused metal-oxide-semiconductor device is physically and electrically connected by an electrical connection in the interconnect structure to a ground terminal 56. The gate 46 of the laterally-diffused metal-oxide-semiconductor device may be physically and electrically connected by an electrical connection in the interconnect structure to a terminal 58 providing a bias voltage. The doped region 44 provides a body contact in the well 30 of the laterally-diffused metal-oxide-semiconductor device, and the doped region 44 is physically and electrically connected by an electrical connection in the interconnect structure to the ground terminal 56.

The device structure 10 includes a silicon-controlled rectifier provided by the doped region 42, the well 24, the portion of the high-voltage well 16 between the well 24 and the well 30, the well 30, and the doped region 34. The doped region 42 of the silicon-controlled rectifier is physically and electrically connected by an electrical connection in the interconnect structure to the drain of the laterally-diffused metal-oxide-semiconductor device and the input/output pad 54. The doped region 34 of the silicon-controlled rectifier is physically and electrically connected by an electrical connection in the interconnect structure to the ground terminal 56. Terminals 60, 62 may be used to respectively supply bias voltages to the high-voltage wells 14, 16. The silicon-controlled rectifier of the device structure 10 is disposed adjacent to the source of the laterally-diffused metal-oxide-semiconductor device.

The device structure 10 may provide an area-efficient electrostatic discharge protection device that integrates a laterally-diffused metal-oxide-semiconductor device configured to protect the input/output pad 54 against an electrode static discharge event and an embedded silicon-controlled rectifier configured to protect the laterally-diffused metal-oxide-semiconductor device against an electrostatic discharge event, even at higher values of gate bias. The triggering of the embedded silicon-controlled rectifier is independent of the triggering of the laterally-diffused metal-oxide-semiconductor device. In that regard, the embedded silicon-controlled rectifier can be configured to trigger before the laterally-diffused metal-oxide-semiconductor device upon the occurrence of an electrostatic discharge event. The performance of the laterally-diffused metal-oxide-semiconductor device is not impacted by the addition of the embedded silicon-controlled rectifier.

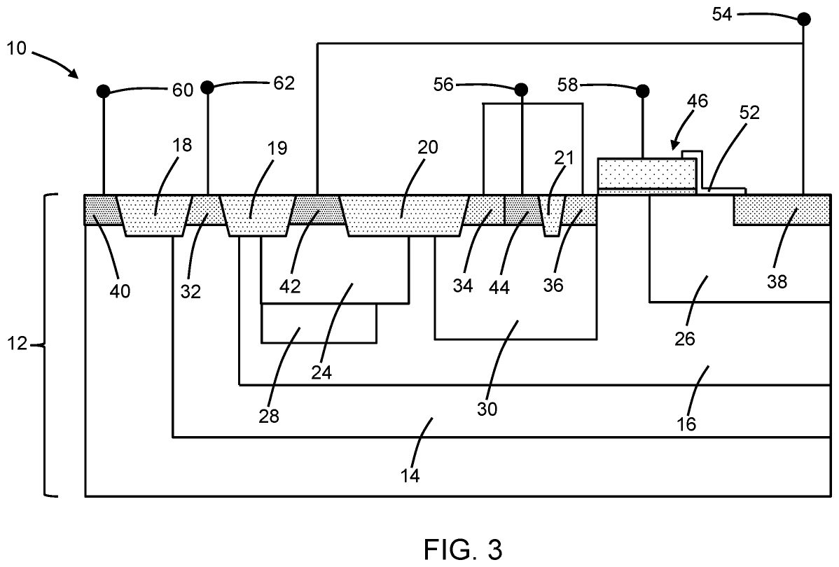

With reference to FIG. 3 in which like reference numerals refer to like features in FIG. 1 and in accordance with alternative embodiments of the invention, the device structure 10 may be modified to eliminate the shallow trench isolation region 22 as a dielectric region in the semiconductor substrate 12 between the gate 46 and the doped region 38. The space in the semiconductor substrate 12 between the gate 46 and the doped region 38 is instead filled by a portion of the well 26.

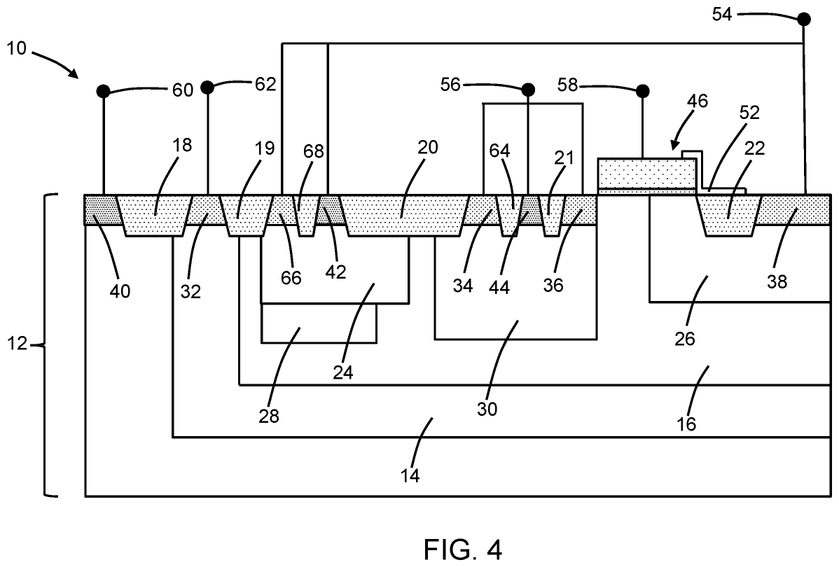

With reference to FIG. 4 and in accordance with alternative embodiments of the invention, the device structure 10 may be modified to add a shallow trench isolation region 64 between the doped region 34 and the doped region 44, a doped region 66 in the well 24 that is doped to have the same conductivity type as the well 24 but at a higher dopant concentration, and a shallow trench isolation region 68 between the doped region 42 and the doped region 66. The doped region 66 may be tied to the drain of the laterally-diffused metal-oxide-semiconductor device and the input/output pad 54. In an alternative embodiment, the device structure 10 may be modified to eliminate the shallow trench isolation region 68 such that the doped region 42 abuts the doped region 66. In an alternative embodiment, the device structure 10 may be modified to eliminate the doped region 66 and the shallow trench isolation region 68 such that only the shallow trench isolation region 64 is added. In an alternative embodiment, the device structure 10 may be modified to eliminate the shallow trench isolation region 64 such that only the doped region 66 and the shallow trench isolation region 68 are added. In an alternative embodiment, the device structure 10 may be further modified to eliminate the shallow trench isolation region 22 as described in connection with FIG. 3.

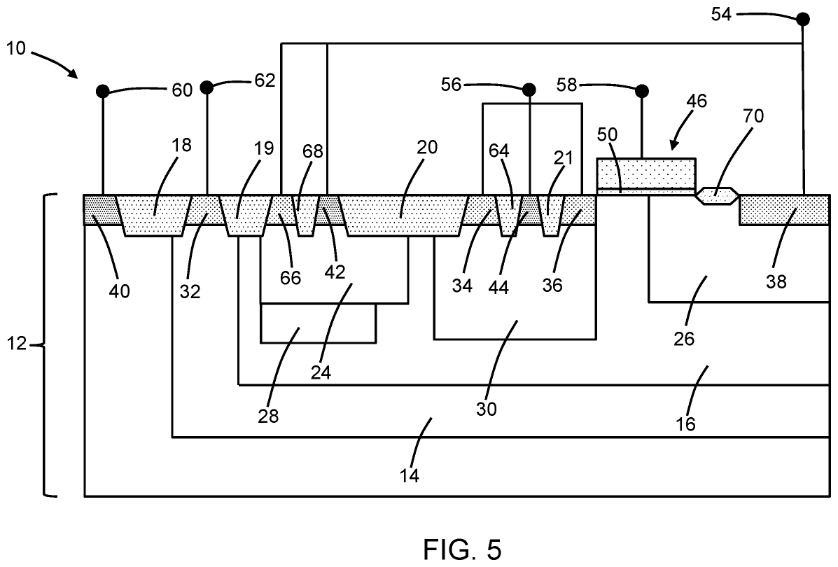

With reference to FIG. 5 and in accordance with alternative embodiments of the invention, the device structure 10 may be modified to add a dielectric region 70 that replaces the shallow trench isolation region 22 in the space within the semiconductor substrate 12 between the gate 46 and the doped region 38. The dielectric region 70 may include a portion that is embedded in the semiconductor substrate 12 and a portion that projects above the top surface 15 of the semiconductor substrate 12. The dielectric region 70, which adjoins the gate dielectric layer 50, is thicker than the gate dielectric layer 50. In alternative embodiments, the shallow trench isolation region 64, the doped region 66, and/or the shallow trench isolation region 68 may be omitted from the embodiment of the device structure 10 with the added dielectric region 70.

In an embodiment, the dielectric region 70 may be comprised of a dielectric material, such as silicon dioxide, that is an electrical insulator. In an embodiment, the dielectric region 70 may be formed as a field oxide by forming a patterned hardmask and subjecting a portion of the semiconductor substrate 12 exposed by the patterned hardmask to thermal oxidation in an oxidizing atmosphere (e.g., an atmosphere with an oxygen content) using a local oxidation of silicon (LOCOS) process. The oxidizing species (e.g., oxygen) is prevented from diffusing through the thickness of the hardmask during thermal oxidation, the portion of the semiconductor substrate 12 exposed by the opening in the hardmask is thermally oxidized to grow the dielectric region 70, and the hardmask is removed following the formation of the dielectric region 70.

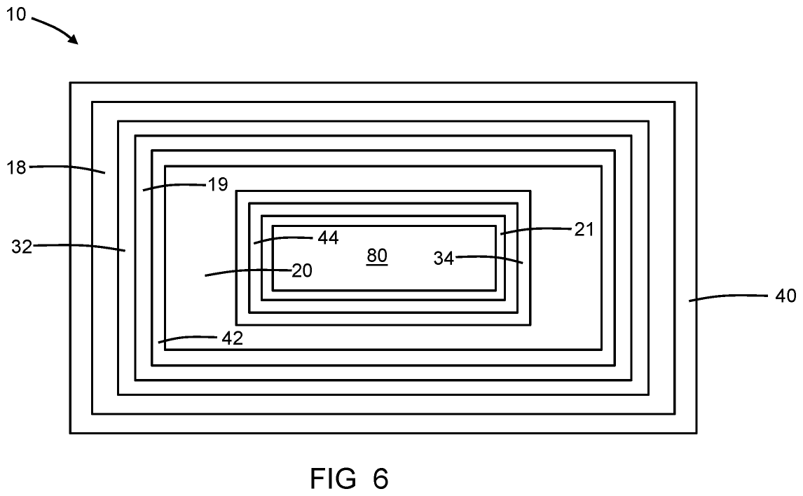

With reference to FIG. 6 and in accordance with embodiments of the invention, the laterally-diffused metal-oxide-semiconductor device may be formed in a device region 80 of the semiconductor substrate 12 that is surrounded by the shallow trench isolation region 21. The doped region 44, the doped region 34, the shallow trench isolation region 20, the doped region 42, the shallow trench isolation region 19, the doped region 32, the shallow trench isolation region 18, and the doped region 40 may surround the shallow trench isolation region 21 and the device region 80. Although not shown, the well 24 and the well 30 also surround the device region 80. Because the silicon-controlled rectifier is disposed in the layout about the perimeter of the device region 80 in which the laterally-diffused metal-oxide-semiconductor device is formed, space is conserved such that the self-protected electrostatic discharge protection device is area-efficient.

The methods as described above are used in the fabrication of integrated circuit chips. The resulting integrated circuit chips can be distributed by the fabricator in raw wafer form (e.g., as a single wafer that has multiple unpackaged chips), as a bare die, or in a packaged form. The chip may be integrated with other chips, discrete circuit elements, and/or other signal processing devices as part of either an intermediate product or an end product. The end product can be any product that includes integrated circuit chips, such as computer products having a central processor or smartphones.

References herein to terms modified by language of approximation, such as “about”, “approximately”, and “substantially”, are not to be limited to the precise value specified. The language of approximation may correspond to the precision of an instrument used to measure the value and, unless otherwise dependent on the precision of the instrument, may indicate a range of +/−10% of the stated value(s).

References herein to terms such as “vertical”, “horizontal”, etc. are made by way of example, and not by way of limitation, to establish a frame of reference. The term “horizontal” as used herein is defined as a plane parallel to a conventional plane of a semiconductor substrate, regardless of its actual three-dimensional spatial orientation. The terms “vertical” and “normal” refer to a direction in the frame of reference perpendicular to the horizontal, as just defined. The term “lateral” refers to a direction in the frame of reference within the horizontal plane.

A feature “connected” or “coupled” to or with another feature may be directly connected or coupled to or with the other feature or, instead, one or more intervening features may be present. A feature may be “directly connected” or “directly coupled” to or with another feature if intervening features are absent. A feature may be “indirectly connected” or “indirectly coupled” to or with another feature if at least one intervening feature is present. A feature “on” or “contacting” another feature may be directly on or in direct contact with the other feature or, instead, one or more intervening features may be present. A feature may be “directly on” or in “direct contact” with another feature if intervening features are absent. A feature may be “indirectly on” or in “indirect contact” with another feature if at least one intervening feature is present. Different features may “overlap” if a feature extends over, and covers a part of, another feature.

The descriptions of the various embodiments of the present invention have been presented for purposes of illustration but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments disclosed herein.

What is claimed is:

1. A structure for an electrostatic discharge protection device, the structure comprising:
a semiconductor substrate including a first well;
a field-effect transistor including a gate, a source having a first doped region in the first well, and a drain; and
a silicon-controlled rectifier including a first doped region in the first well.

2. The structure of claim 1 wherein the semiconductor substrate includes a second well adjacent to the first well, and the silicon-controlled rectifier includes a second doped region in the second well.

3. The structure of claim 2 wherein the semiconductor substrate includes a third well adjacent to the first well, the drain of the field-effect transistor includes a second doped region in the third well, and further comprising:
an input-output terminal coupled to the second doped region of the silicon-controlled rectifier and to the second doped region of the field-effect transistor.

4. The structure of claim 2 further comprising:
a first shallow trench isolation region in the semiconductor substrate, the first shallow trench isolation region between the first doped region of the silicon-controlled rectifier and the second doped region of the silicon-controlled rectifier, the first shallow trench isolation region including a first portion that overlaps with the first well, and the first shallow trench isolation region including a second portion that overlaps with the second well.

5. The structure of claim 4 further comprising:
a second shallow trench isolation region in the semiconductor substrate,
wherein the second doped region of the silicon-controlled rectifier is disposed between the first shallow trench isolation region and the second shallow trench isolation region.

6. The structure of claim 5 wherein the semiconductor substrate has a top surface, and the first shallow trench isolation region, the second shallow trench isolation region, and the second doped region of the silicon-controlled rectifier are disposed fully between the second well and the top surface of the semiconductor substrate.

7. The structure of claim 2 wherein the semiconductor substrate includes a third well, the first well is disposed in a lateral direction between the second well and the third well, the drain of the field-effect transistor includes a second doped region in the third well, and the third well includes a portion beneath the gate of the field-effect transistor.

8. The structure of claim 7 wherein the semiconductor substrate includes a deep well having an opposite conductivity type from the second well and the third well, and the second well and the third well are disposed within the deep well.

9. The structure of claim 7 wherein the second doped region has a conductivity type, and the third well has the conductivity type at a lower dopant concentration than the second doped region.

10. The structure of claim 1 wherein the first doped region of the silicon-controlled rectifier has a first conductivity type, the first well has a second conductivity type opposite from the first conductivity type, and the first doped region of the field-effect transistor has the first conductivity type.

11. The structure of claim 10 wherein the first conductivity type is n-type, and the second conductivity type is p-type.

12. The structure of claim 1 wherein the first doped region of the source of the field-effect transistor and the first doped region of the silicon-controlled rectifier are coupled to a ground potential.

13. The structure of claim 1 wherein the field-effect transistor includes a body contact in the first well, and further comprising:
a first shallow trench isolation region in the semiconductor substrate between the body contact and the first doped region of the source of the field-effect transistor.

14. The structure of claim 13 further comprising:
a second shallow trench isolation region in the semiconductor substrate between the body contact of the field-effect transistor and the first doped region of the silicon-controlled rectifier.

15. The structure of claim 1 further comprising:
a shallow trench isolation region in the semiconductor substrate between the gate of the field-effect transistor and the drain of the field-effect transistor.

16. The structure of claim 1 further comprising:
a dielectric region in the semiconductor substrate between the gate of the field-effect transistor and the drain of the field-effect transistor.

17. The structure of claim 1 wherein the silicon-controlled rectifier is adjacent to the source of the field-effect transistor.

18. The structure of claim 1 further comprising:
a shallow trench isolation region in the semiconductor substrate between the first doped region of the source of the field-effect transistor and the first doped region of the silicon-controlled rectifier.

19. The structure of claim 1 wherein the semiconductor substrate has a top surface, the first doped region of the source of the field-effect transistor adjoins the top surface, and the first doped region of the silicon-controlled-rectifier adjoins the top surface.

20. A method of forming a structure for an electrostatic discharge protection device, the method comprising:
forming a well in a semiconductor substrate;
forming a field-effect transistor that includes a gate, a source having a doped region in the well, and a drain; and
forming a silicon-controlled rectifier that includes a doped region in the well.
